(19) United States
(12) Patent Application Publication
(10) Pub. No.: US 2011/0222001 A1
(43) Pub. Date: Sep. 15, 2011

(54) DISPLAY PANEL SUBSTRATE AND DISPLAY PANEL

(75) Inventor: Takahiro Umezawa, Osaka (JP)

(73) Assignee: Sharp Kabushiki Kaisha, Osaka (JP)

(21) Appl. No.: 13/130,042

(22) PCT Filed: Nov. 13, 2009
(86) PCT No.: PCT/JP2009/069354

§ 371 Date: May 18, 2011

(30) Foreign Application Priority Data
Nov. 21, 2008 (JP) 2008-298254

(51) Int. Cl. G02F 1/1333; H05K 1/02

(52) U.S. Cl. 349/84; 174/251

(57) ABSTRACT

Provided are a display panel substrate and a display panel which are capable of preventing short-circuiting between wiring electrode terminals. The substrate includes wiring electrode terminals (121) for connecting an external wiring substrate; lead wires (122) electrically connected to the wiring electrode terminals (121); an interlayer insulating film (209) covering the lead wires (122); conductive material films (210) formed to overlap the wiring electrode terminals (121) and electrically connected to the wiring electrode terminals (121); and conductive material films (211) formed to overlap the lead wires (122) through the interlayer insulating film (209) and electrically connected to the lead wires (122). The conductive material films (210), which are formed to overlap the wiring electrode terminals (121), and the conductive material films (211), which are formed to overlap the lead wires (122) through the interlayer insulating film (209), are separated from each other in the border portion of the interlayer insulating film (209).

### TECHNICAL FIELD

The present invention relates to a display panel substrate and a display panel. More particularly, the present invention relates to a display panel substrate on which terminals (specifically, band plate-shaped lands, for example) for establishing electrical connections to TCP (Tape Carrier Package) and the like are provided in the peripheral portion, and a display panel having the display panel substrate.

### BACKGROUND ART

Generally, a liquid crystal display panel includes two substrates. For example, an active matrix type liquid crystal display panel includes a TFT array substrate and an opposite substrate (a color filter, for example, can be applied to the opposite substrate). These substrates are bonded together such that they face each other with a predetermined narrow spacing in between. The spacing between the substrates is filled with liquid crystal.

On the surface of the TFT array substrate, a display region (also called “active area”) and a panel frame region that surrounds the display region are provided. On the display region, a plurality of pixel electrodes are arranged in a matrix, and switching elements (thin film transistors (TFTs), for example) for driving the pixel electrodes on an electrode by electrode basis are also arranged. Furthermore, scanning lines (also called “gate bus lines”) and data lines (also called “source bus lines”) for sending prescribed signals to each of the switching elements are formed on the display region. In the panel frame region, on the other hand, wiring electrode terminals (lands, for example) for connecting TCPs (Tape Carrier Packages) or the like on which driver ICs (source driver or gate driver, for example) are mounted are formed. Furthermore, in the panel frame region, wirings are formed to connect the terminals to corresponding scanning lines or corresponding data lines formed in the display region.

In such configuration, signals generated by the driver IC mounted on the TCP is transmitted to the scanning line or the data line formed on the display region via the wiring electrode terminal and the wiring provided in the panel frame region. The signals are then distributed to each switching element via the scanning line or the data line.

In some cases, terminals and wirings formed in the panel frame region have the following structures. That is, on the surface of the display panel substrate, wiring electrode terminals and wirings are formed of the same material in the same layer (the layer immediately above a transparent substrate made of, for example, glass). The terminals are formed in the shape of a thin, long band plate. The wiring electrode terminals are disposed in plurality in the border portion of the panel frame region, arranged approximately in parallel with each other, with a certain interval in between. An interlayer insulating film is formed in the panel frame region except for the region where the wiring electrode terminals are formed. Therefore, the wirings are covered by the interlayer insulating film, but the wiring electrode terminals are not covered by the interlayer insulating film and are exposed.

A conductive material film (a film made of indium tin oxide, for example) is formed on the surface of the wiring electrode terminal. A conductive material film is also formed over the wiring, with the interlayer insulating film sandwiched in between. Contact holes are formed in the interlayer insulating film at prescribed locations. The wiring and the conductive material film are electrically connected to each other via the contact holes. In this configuration, the wiring electrode terminal and the wiring have multi-layered structure, which reduces the electrical resistance of the wiring electrode terminal and the wiring. As a result, the loss of signals transmitted can be minimized.

The conductive material film described above can be formed by photolithography. The method is briefly described as follows. First, a conductive material film is formed over about the entire surface of the display panel substrate on which the wiring electrode terminal and wiring patterns, and the interlayer insulating film are formed. Next, a photoresist material film is formed to cover the conductive material film. Then, the photoresist material film is irradiated with light energy through a photomask on which prescribed light-shielding pattern and light-transmitting pattern are formed. For example, if the photoresist material is of positive type, portions of the photoresist material film formed on the surface of the wiring electrode terminal and on the surface of wiring are shielded from the light, and portions of the photoresist material film formed between the wiring electrode terminals and between the wirings are irradiated with the light energy.

Next, a prescribed portion of the photoresist material that has been exposed to the light is removed by development. If the photoresist material is a positive type, the portion exposed to the light energy is removed, and the portion shielded from the light is preserved. Therefore, the photoresist material film remains on the surfaces of the wiring electrode terminal and the wiring, and the photoresist material film is removed from between the wiring electrode terminals and between wirings. As a result, of the conductive material film, the portions between the wiring electrode terminals and between the wiring are exposed.

Subsequently, using the photoresist material film that has been formed into the prescribed pattern as a mask, the conductive material film is patterned by etching. As a result, the exposed conductive material film is removed. More specifically, of the conductive material film, the portion overlapping the surface of the wiring electrode terminal and a portion overlapping the surface of the wiring via the interlayer insulating film remain, and the portions formed between the wiring electrode terminals and between wirings are removed. As a result, the wiring electrode terminal and the wiring have a multi-layered structure.

Recently, there are demands for reduction in the required number of driver ICs to lower the cost. To reduce the required number of the driver ICs, each of the driver ICs used needs to have a larger number of output terminals. When the number of output terminals of the driver IC mounted on TCP increases, the number of terminals connected between TCP and a display panel substrate also increases. Therefore, the intervals between the wiring electrode terminals or between the wirings formed on the display panel substrate need to be narrowed. As the intervals between the wiring electrode terminals or between the wirings are narrowed, the chance of short-circuiting occurring between the wiring electrode terminals or between the wirings increases. In particular, the chance of short-circuiting occurring through the conductive material film overlapping the wiring electrode terminals or the wirings increases.

The reason is as follows. As described above, the conductive material film is formed by photolithography. That is, the conductive material film is formed first, and then, a photoresist material film is formed on the surface of the conductive material film. Next, the photoresist material film is patterned. Subsequently, the conductive material film is patterned using the patterned photoresist material film as a mask.

The photoresist material film is also formed on the stepped surface of the border portion of the interlayer insulating film. The thickness of the photoresist material film formed on the stepped surface of the border portion of the interlayer insulating film depends on the thickness of the interlayer insulating film. That is, the thickness of the photoresist material film is approximately the same as the height of the stepped surface of the border portion of the interlayer insulating film. Therefore, the thickness of the photoresist material film formed on the stepped surface of the border portion of the interlayer insulating film becomes thicker than other area. A thicker photoresist material film can cause insufficient light exposure in the light exposure process.

If the photoresist material film is a positive type, the photoresist in the area that is not subjected to sufficient light exposure may not completely be removed by development. Because the photoresist material film that is preserved becomes the etching mask when the conductive material film is patterned, the conductive material film that is covered by any residue of the photoresist material film is preserved. As a result, the conductive material film remains between wiring electrode terminals and between the wirings in the border portion of the interlayer insulating film. The conductive material film that remains causes short-circuiting between the adjacent terminals and between the adjacent wirings.

Configurations for preventing the short-circuiting between the terminals and between the wirings due to the residual conductive material film are disclosed in Patent Document 1 and Patent Document 2, for example. According to the configuration disclosed in Patent Document 1, a wall of an interlayer insulating film is formed between the terminals to prevent short-circuiting between the terminals. According to the configuration disclosed in Patent Document 2, the surface of the interlayer insulating film is smoothed to control the etching condition of the conductive material film formed thereon, thereby preventing the short-circuiting between the terminals. In these configurations, the conductive material film can be prevented from being formed between the terminals, and therefore the short-circuiting between the terminals can be prevented. However, neither Patent Document 1 nor Patent Document 2 provide a solution for preventing the formation of the residual photoresist material film in the border portion of the interlayer insulating film.

### RELATED ART DOCUMENTS

### Patent Documents

Patent Document 1: Japanese Patent Application Laid-Open Publication No. 2000-180890
Patent Document 2: Japanese Patent Application Laid-Open Publication No. 2000-155335

### SUMMARY OF THE INVENTION

### Problems to be Solved by the Invention

The present invention was devised in consideration of the current situation described above, and aims at providing a display panel substrate, a display panel, a method for manufacturing such a display panel substrate, capable of preventing short-circuiting between wiring electrode terminals; providing a display panel substrate, a display panel, a method for manufacturing such a display panel substrate, capable of preventing short-circuiting between terminals caused by a conductive material film that is formed to overlap the wiring electrode terminals or wirings; and providing a display panel substrate, a display panel, a method for manufacturing such a display panel substrate, capable of preventing short-circuiting between wiring electrode terminals caused by a photoresist material film residue in a border portion of an interlayer insulating film.

### Means for Solving the Problems

To solve the problems described above, the present invention includes a plurality of wiring electrode terminals for connecting external wiring substrates; a plurality of lead wires respectively and electrically connected to the plurality of wiring electrode terminals; an interlayer insulating film covering the plurality of lead wires; a conductive material film formed to overlap respective one of the wiring electrode terminals, and electrically connected to the respective one of the plurality of wiring electrode terminals; and a conductive material film formed to overlap respective one of the plurality of lead wires with the interlayer insulating film sandwiched in between, and electrically connected to the respective one of the plurality of lead wires, wherein the plurality of lead wires are formed in parallel with each other, and, in a border portion of the interlayer insulating film, a portion of the interlayer insulting film that is formed in between the plurality of lead wires has a smaller thickness than a portion formed to overlap the plurality of lead wires.

In an applicable configuration, the conductive material film, which is formed to overlap the lead wire through the interlayer insulating film sandwiched and is electrically connected to the lead wire, is electrically connected to the lead wire through an opening formed in the interlayer insulating film.

In an applicable configuration, the conductive material film formed to overlap the respective one of the plurality of wiring electrode terminals, and the conductive material film formed to overlap the respective one of the plurality of lead wires through the interlayer insulating film are separated from each other at the border portion of the interlayer insulating film; and the conductive material films formed respectively to overlap the plurality of the lead wires, which are arranged side by side, through the interlayer insulating film are separate from each other.

In an applicable configuration, in the conductive material film formed to overlap the lead wire through the interlayer insulating film, a portion in proximity to the border portion of the interlayer insulating film has a smaller width than other portions.

In an applicable configuration, in the conductive material film formed to overlap the lead wire through the interlayer insulating film, a portion in proximity to the border portion of the interlayer insulating film is formed to have a smaller width than other portions, and the portion having a smaller width than other portions has a wider interval between itself and the conductive material film formed to overlap an adjacent lead wire through the interlayer insulating film.

The present invention is summarized a display panel including a display panel substrate and an opposite substrate, wherein the display panel substrate and the opposite substrate are disposed opposite to each other with a prescribed space in between, and the space between the display panel substrate and the opposite substrate is filled with liquid crystal.

### EFFECTS OF THE INVENTION

According to the present invention, at the border portion of the interlayer insulating film, the portion formed between the plurality of lead wires has a smaller thickness than the portion formed to overlap the respective one of the plurality of lead wires. In such configuration, when a conductive material film is formed on the surface of the interlayer insulating film using photolithography, a photoresist material film formed on the stepped surface of the border portion of the interlayer insulating film can be made thin. That is, in the manufacturing step in which a photoresist material film is formed on the surface of the interlayer insulating film, the photoresist material film is formed on the stepped surface of the border portion of the interlayer insulating film. The thickness of the photoresist material film formed on the stepped surface of the border portion of the interlayer insulating film depends on the thickness of the interlayer insulating film also. Therefore, if the interlayer insulating film formed between the lead wires is thinner than other portion of the interlayer insulating film, the thickness of the photoresist material film formed between the lead wires becomes small. By reducing the thickness of the photoresist material film, insufficient light exposure in the light exposure process can be prevented. Consequently, if the photoresist material film is a positive type, formation of a residual photoresist material film between the lead wires in the development process can be prevented. This means that, in the process of patterning the conductive material film using the photoresist material film as a mask, formation of a residual conductive material film between the lead wires can be prevented. This way, short-circuiting between the adjacent lead wires due to the conductive material film can be prevented or suppressed.

The conductive material film formed to overlap the wiring electrode terminal and the conductive material film to overlap the lead wire through the interlayer insulating film are separated in the border portion of the interlayer insulating film. That is, the conductive material film is not formed in the border portion of the interlayer insulating film. Consequently, in the border portion of the interlayer insulating film, short-circuiting between the adjacent wiring electrode terminals due to the conductive material film formed to overlap the wiring electrode terminal, and short-circuiting between adjacent lead wires due to the conductive material film overlapping the lead wire through the interlayer insulating film can be prevented or suppressed.

In the conductive material film formed to overlap the lead wire through the interlayer insulating film, the portion in proximity to the border portion of the interlayer insulating film has a smaller width than other portion. Therefore, the interval between the adjacent conductive material films becomes greater in the border portion of the interlayer insulating film. Consequently, in the border portion of the interlayer insulating film, short-circuiting between the adjacent lead wires due to the conductive material film overlapping the lead wires through the interlayer insulating film can be prevented or suppressed.

### BRIEF DESCRIPTION OF THE DRAWINGS

FIG. 1 is a schematic perspective view of a display panel substrate according to an embodiment of the present invention, showing an overview of the external configuration.

FIG. 2 is a schematic plan view showing an arrangement of pixels and wirings disposed on the display region.

FIG. 3 is an enlarged schematic plan view of a portion of a terminal region of a display panel substrate according to an embodiment of the present invention.

FIG. 4 (a) is a cross-sectional view taken along the line A-A of FIG. 3. FIG. 4 (b) is a cross-sectional view taken along the line B-B of FIG. 3. FIG. 4 (c) is a cross-sectional view taken along the line C-C of FIG. 3.

FIG. 5 schematically shows cross-sectional views of particular steps of forming a wiring electrode terminal, a lead wire, an interlayer insulating film, and other elements. FIG. 5(a) is a cross-sectional view taken along the line A-A of FIG. 3. FIG. 5(b) is a cross-sectional view taken along the line B-B of FIG. 3. FIG. 5(c) is a cross-sectional view taken along the line C-C of FIG. 3.

FIG. 6 schematically shows cross-sectional views of particular steps of forming a wiring electrode terminal, a lead wire, an interlayer insulating film, and other elements. FIG. 6(a) is a cross-sectional view taken along the line A-A of FIG. 3. FIG. 6(b) is a cross-sectional view taken along the line B-B of FIG. 3. FIG. 6(c) is a cross-sectional view taken along the line C-C of FIG. 3.

FIG. 7 schematically shows cross-sectional views of particular steps of forming a wiring electrode terminal, a lead wire, an interlayer insulating film, and other elements. FIG. 7(a) is a cross-sectional view taken along the line A-A of FIG. 3. FIG. 7(b) is a cross-sectional view taken along the lines B-B of FIG. 3. FIG. 7(c) is a cross-sectional view taken along the lines C-C of FIG. 3.

FIG. 8 schematically shows cross-sectional views of particular steps of forming a wiring electrode terminal, a lead wire, an interlayer insulating film, and other elements. FIG. 8(a) is a cross-sectional view taken along the line A-A of FIG. 3. FIG. 8(b) is a cross-sectional view taken along the lines B-B of FIG. 3. FIG. 8(c) is a cross-sectional view taken along the lines C-C of FIG. 3.

FIG. 9 schematically shows cross-sectional views of particular steps of forming a wiring electrode terminal, a lead wire, an interlayer insulating film, and other elements. FIG. 9(a) is a cross-sectional view taken along the line A-A of FIG. 3. FIG. 9(b) is a cross-sectional view taken along the lines B-B of FIG. 3. FIG. 9(c) is a cross-sectional view taken along the lines C-C of FIG. 3.

FIG. 10 schematically shows cross-sectional views of particular steps of forming a wiring electrode terminal, a lead wire, an interlayer insulating film, and other elements. FIG. 10(a) is a cross-sectional view taken along the line A-A of FIG. 3. FIG. 10(b) is a cross-sectional view taken along the lines B-B of FIG. 3. FIG. 10(c) is a cross-sectional view taken along the lines C-C of FIG. 3.

FIG. 11 schematically shows cross-sectional views of particular steps of forming a wiring electrode terminal, a lead wire, an interlayer insulating film, and other elements. FIG. 11(a) is a cross-sectional view taken along the line A-A of FIG. 3. FIG. 11(b) is a cross-sectional view taken along the lines B-B of FIG. 3. FIG. 11(c) is a cross-sectional view taken along the lines C-C of FIG. 3.

FIG. 12 schematically shows cross-sectional views of particular steps of forming a wiring electrode terminal, a lead wire, an interlayer insulating film, and other elements. FIG. 12(a) is a cross-sectional view taken along the line A-A of FIG. 3. FIG. 12(b) is a cross-sectional view taken along the lines B-B of FIG. 3. FIG. 12(c) is a cross-sectional view taken along the lines C-C of FIG. 3.

FIG. 13 schematically shows cross-sectional views of particular steps of forming a wiring electrode terminal, a lead wire, an interlayer insulating film, and other elements. FIG. 13(a) is a cross-sectional view taken along the line A-A of FIG. 3. FIG. 13(b) is a cross-sectional view taken along the lines B-B of FIG. 3. FIG. 13(c) is a cross-sectional view taken along the lines C-C of FIG. 3.

FIG. 14 schematically shows cross-sectional views of particular steps of manufacturing a display panel substrate according to an embodiment of the present invention.

FIG. 15 schematically shows cross-sectional views of particular steps of manufacturing a display panel substrate according to an embodiment of the present invention.

FIG. 16 schematically shows cross-sectional views of particular steps of manufacturing a display panel substrate according to an embodiment of the present invention.

FIG. 17 schematically shows cross-sectional views of particular steps of manufacturing a display panel substrate according to an embodiment of the present invention.

FIG. 18 schematically shows cross-sectional views of particular steps of manufacturing a display panel substrate according to an embodiment of the present invention.

FIG. 19 schematically shows cross-sectional views of particular steps of manufacturing a display panel substrate according to an embodiment of the present invention.

FIG. 20 schematically shows the configuration of a color filter. FIG. 20(a) is a schematic perspective view illustrating the overall structure of a color filter. FIG. 20(b) is a plan view showing the configuration of a single pixel formed on a color filter. FIG. 20(c) is a cross-sectional view taken along the line F-F of FIG. 20(b), illustrating a structure of a pixel.

FIG. 21 schematically shows a cross-sectional view showing the structure of a part of a display panel according to an embodiment of the present invention.

### DETAILED DESCRIPTION OF EMBODIMENTS

Below, embodiments of the present invention are described in detail with reference to figures. Display panel substrates according to embodiments of the present invention are TFT array substrates used for active matrix type liquid crystal display panels.

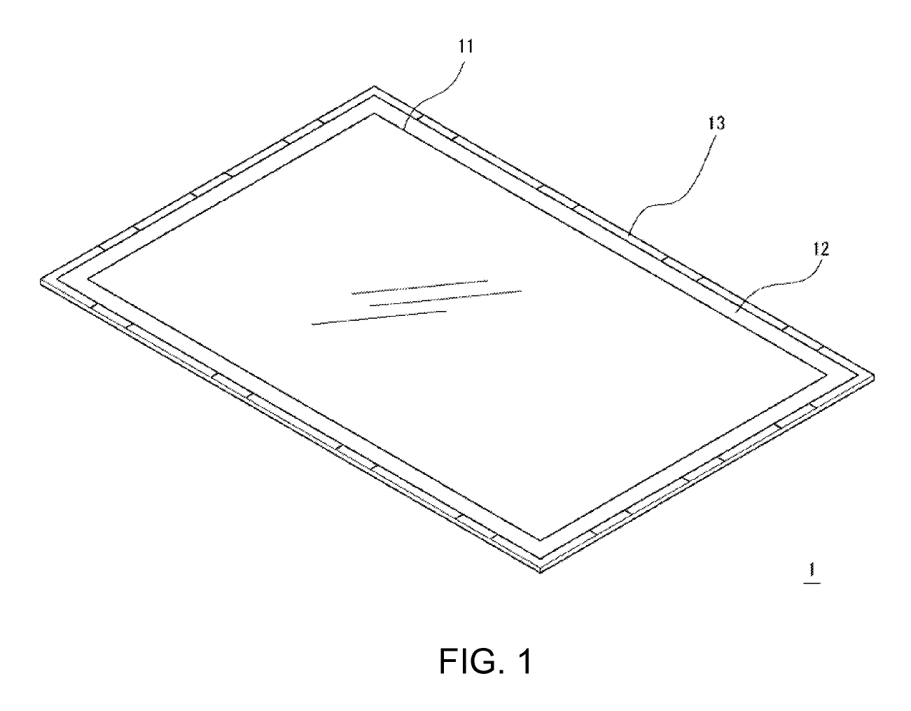

FIG. 1 is a schematic perspective view of a display panel substrate 1 according to embodiments of the present invention, showing an overview of the external configuration. As shown in FIG. 1, the display panel substrate 1 according to embodiments of the present invention includes a display region (also called “active region”) 11. A panel frame region 12 is provided outside the display region 11, surrounding the display region 11.

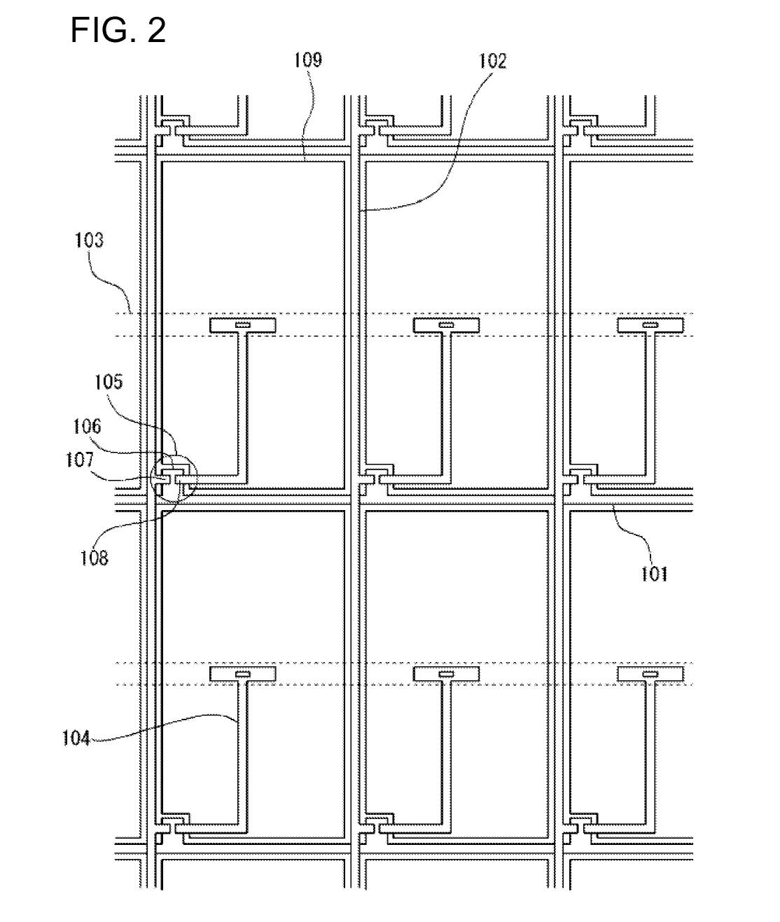

FIG. 2 is a schematic plan view showing the arrangement of pixels and wirings disposed on the display region 11. As shown in FIG. 2, a plurality of pixels are arranged in a matrix in the display region 11. Each pixel has a pixel electrode 109 and a switching element 105 (specifically, this is a thin film transistor (TFT), for example) that drives the pixel electrode 109. The pixel electrode 109 and a drain electrode 108 of the switching element 105 are electrically connected via a drain line 104. In some cases, slits for controlling the liquid crystal alignment are formed in the pixel electrode 109, but they are omitted in FIG. 2.

In the display region 11, a plurality of scanning lines 101 (also called “gate bus lines”) are formed approximately in parallel with each other. Between the scanning lines 101, an auxiliary capacitance lines 103 (also called “storage capacitance lines”) are arranged approximately in parallel with the scanning lines 101. Furthermore, a plurality of data lines 102 (also called “source bus lines”) are arranged in parallel with each other and approximately perpendicularly to the scanning lines 101 and the auxiliary capacitance lines 103.

A switching element 105 that drives a pixel electrode 109 is provided near the intersection of the scanning line 101 and the data line 102. The switching element 105 has a gate electrode 106, a source electrode 107, and a drain electrode 108. The gate electrode 106 is electrically connected to the scanning line 101. The source electrode 107 is electrically connected to the data line 102. The drain electrode 108 is electrically connected to the pixel electrode 109 via the drain line 104. The auxiliary capacitance line 103 forms an auxiliary capacitance (also called “storage capacitance”) with a particular pixel electrode 109. With this configuration, the scanning line 101 can transmits particular gate signals (also called “select pulse”) to the gate electrode 106 of a particular switching element 105. Also, the data line 102 can transmit data signals to the source electrode 107 of a particular switching element 105.

FIG. 1 is referenced again. A panel frame region 12 is provided around the display region 11, surrounding the display region 11. A terminal region 13 is provided in the outer peripheral area of the panel frame region 12. The terminal region 13 is a region where TCPs (Tape Carrier Package), on which driver ICs (or driver LSI) are mounted and anisotropic conductive films (ACF) are bonded, are connected.

Wiring electrode terminals 121 are formed in the terminal region 13. The wiring electrode terminals 121 are terminals that are electrically connected to wirings or a terminals formed on a TCP (Tape Carrier Package) on which a driver IC (or driver LSI) is mounted. The wiring electrode terminal 121 is a thin band plate-shaped land made of, for example, an electrically conductive material. A plurality of wiring electrode terminals 121 are formed approximately in parallel with each other at a prescribed interval in between.

In the panel frame region 12 other than the terminal region 13, wirings 122 (the wirings are referred to as “lead wire 122” for convenience), which electrically connect particular wiring electrode terminals 121 to particular scanning lines 101, data lines 102 or auxiliary capacitance lines 103 formed in the display region 11, are disposed.

Anisotropic conductive films are disposed on the terminal region 13. With the anisotropic conductive films, TCPs on which driver ICs and other devices are mounted are fixed to the terminal region 13. When a TCP is fixed to the terminal region with an anisotropic conductive film, particular wirings or terminals formed on the TCP and particular wiring electrode terminals 121 formed on the terminal region 13 are electrically connected to each other. In this configuration, particular signals generated by the driver IC and other elements mounted on the TCP are transmitted to particular wirings (that is, particular scanning lines 101, auxiliary capacitance lines 103, or data lines 102) provided on the display region 11 via the wiring electrode terminals 121 and lead wires provided in the panel frame region 12.

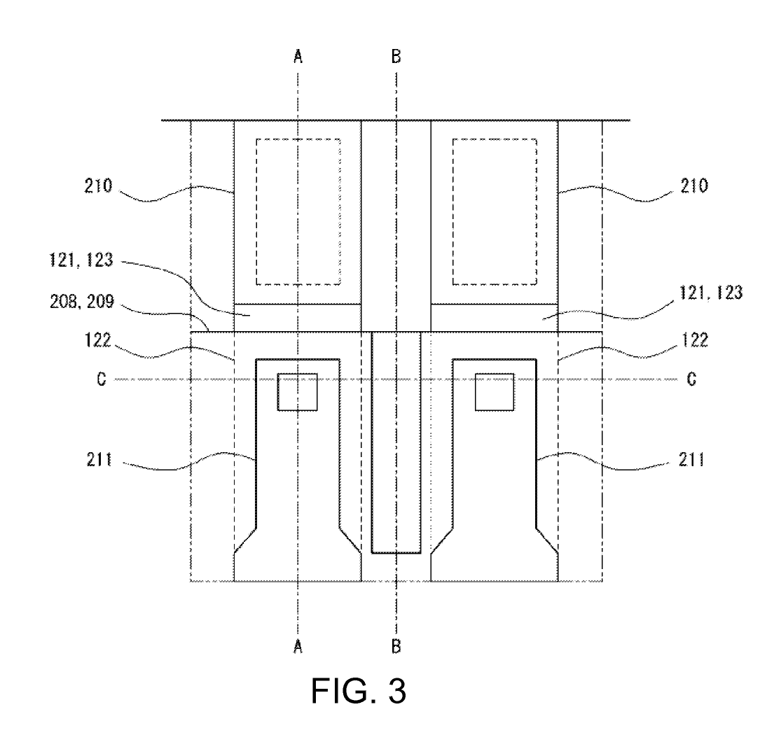

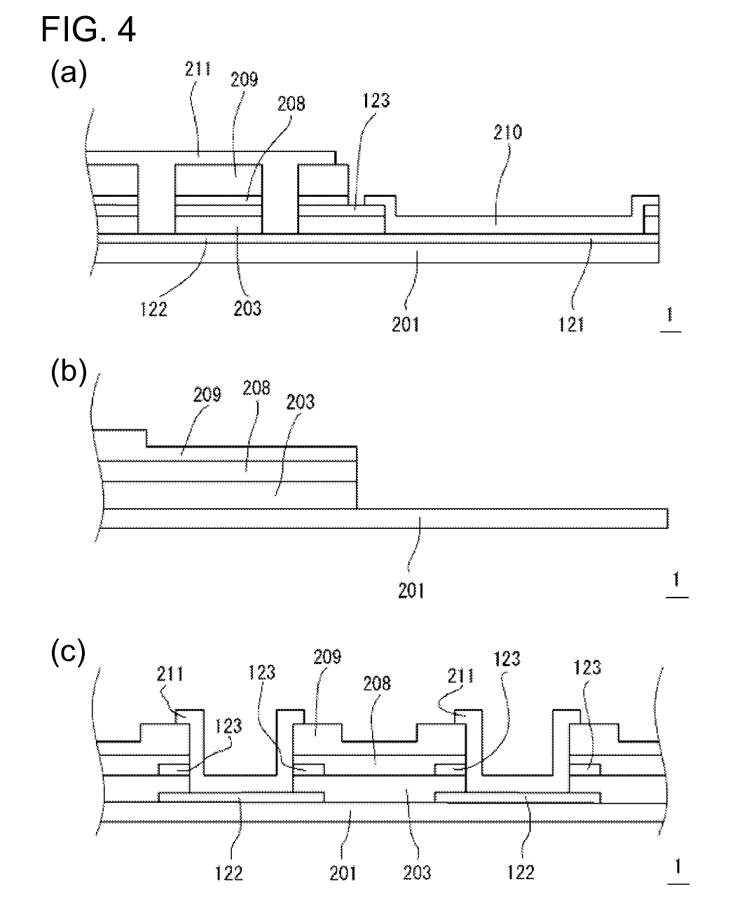

FIG. 3 is an enlarged schematic plan view of a portion of the terminal region 13 of the display panel substrate 1 according to an embodiment of the present invention. FIG. 4(a) is a cross-sectional view taken along the line A-A of FIG. 3. FIG. 4(b) is a cross-sectional view taken along the line B-B of FIG. 3. FIG. 4(c) is a cross-sectional view taken along the line C-C of FIG. 3.

As shown in FIG. 3, in the panel frame region 12 of the display panel substrate 1 according to an embodiment of the present invention, a plurality of band plate-shaped wiring electrode terminals 121 and lead wires 122 are arranged approximately in parallel with each other at a prescribed interval in between. The wiring electrode terminal 121 is not covered by the interlayer insulating film 209, but the lead wire 122 is covered by the interlayer insulating film 209. On the surface of the wiring electrode terminal 121, a conductive material film 210 is formed. Also, on the surface of the interlayer insulating film 209, a conductive material film 211 is formed, overlapping the lead wire 122 with the interlayer insulating film 209 sandwiched in between.

As shown in FIGS. 4(a) and 4(c), on the surface of the display panel substrate 1 according to an embodiment of the present invention, the wiring electrode terminal 121 and the lead wire 122 are formed of the same material as a single unit. The wiring electrode terminal 121 and the lead wire 122 are covered with a first insulating film 203. On the surface of the first insulating film 203, a sub wiring 123 is formed to overlap the wiring electrode terminal 121 and the lead wire 122 with the first insulating film 203 sandwiched in between.

In the first insulating film 203 and the sub wiring 123, an opening (contact hole) is formed at a location overlapping the wiring electrode terminal 121. The surface of the wiring electrode terminal 121 is exposed through this opening. Furthermore, a conductive material film 210 is formed to overlap the wiring electrode terminal 121. Specifically, the conductive material film 210 is formed so as to cover the surface of the wiring electrode terminal 121 exposed through the opening formed in the first insulating film 203 and the sub wiring 123 to cover the border portions of this opening. As a result, the wiring electrode terminal 121 and sub wiring 123 are electrically connected to each other via the conductive material film 210.

Openings (contact holes) are formed running through the first insulating film 203, the sub wiring 123 and the interlayer insulating film 209 that overlap the lead wire 122. As a result, the lead wire 122 is partially exposed through these openings. On the surface of the interlayer insulating film 209, a conductive material film 211 is formed to overlap the lead wire 122, with the first insulating film 203, the sub wiring 123, and the interlayer insulating film 209 sandwiched in between. The conductive material film 211 is also formed inside the opening that runs through the first insulating film 203, the sub wiring 123, and the interlayer insulating film 209. As a result, the lead wire 122 and the sub wiring 123 are electrically connected via the conductive material film 211.

In such configuration, prescribed electrical signals can be transmitted through the sub wiring 123 and the conductive material films 210 and 211 as well as through the wiring electrode terminal 121 and the lead wire 122. That is, this configuration essentially reduces the electrical resistance, which is in effect equivalent to increasing the cross-sectional area of the wiring electrode terminal 121 and the lead wire 122. As a result, the loss in the electrical signals transmitted through the wiring electrode terminal 121 and the lead wire 122 can be minimized.

As shown in FIG. 3 and FIG. 4(a), conductive material film 210 is not formed on the border portion of the interlayer insulating film 209. Therefore, the conductive material film 210 formed to overlap the wiring electrode terminal 121 and the conductive material film 211 formed on the surface of the interlayer insulating film 209 are physically separate. With such configuration, in the border portion of the interlayer insulating film 209, short-circuiting between the adjacent wiring electrode terminals 121 via the conductive material film 210 can be prevented. Likewise, short-circuiting between the adjacent lead wires 122 via the conductive material film 211 can also be prevented.

As shown in FIGS. 4(b) and 4(c), of the border portion of the interlayer insulating film 209, the portion formed between the lead wires 122 (that is, the portion not overlapping the lead wire 122) has a smaller thickness than the portion formed on the surface of the lead wire 122 (that is, the portion overlapping the lead wire 122). Therefore, the border portion of the interlayer insulating film 209 becomes thinner in stages.

As shown in FIG. 3, of the conductive material film 211 formed on the interlayer insulating film 209, the portion in proximity to the thin portion of the interlayer insulating film 209 has a smaller width than other portions. That is, on the side close to the display region 11, the width of the conductive material film 211 is about the same as the width of the lead wire 122, but on the side close to wiring electrode terminal 121 (the portion in proximity to the thin portion of the interlayer insulating film 209) has a smaller width than the lead wire 122. In such configuration, in the border portion of the interlayer insulating film 209, the space between the adjacent conductive material films 211 becomes wider. As a result, short circuit between adjacent lead wires 122 via the conductive material film 211 can be prevented.

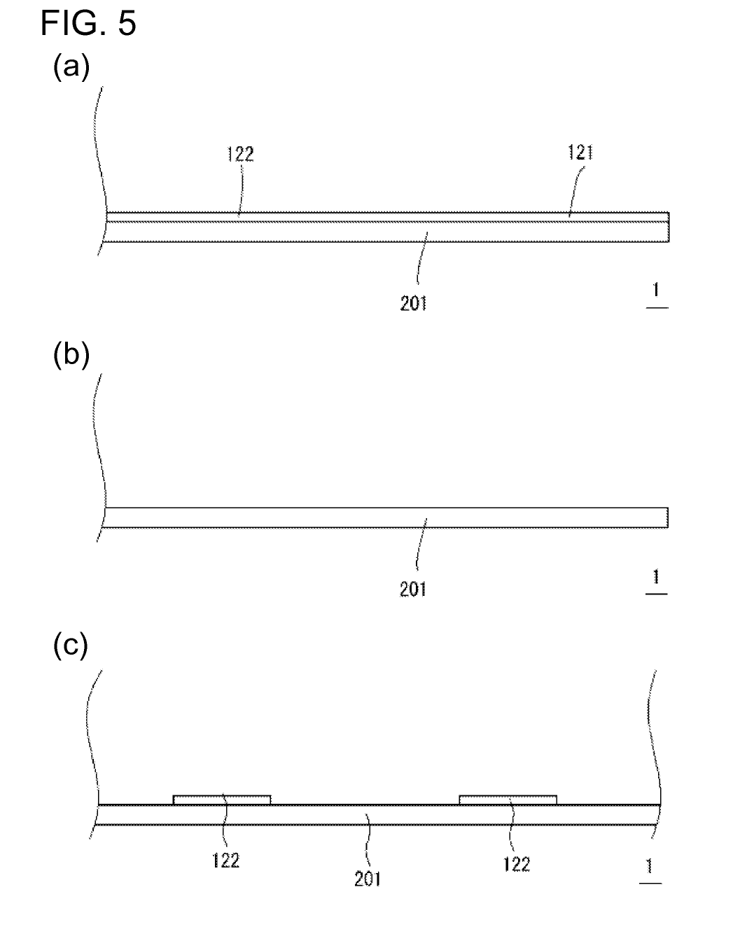

The wiring electrode terminal 121, lead wire 122, and interlayer insulating film 209 and other elements in this configuration are manufactured as described below. FIG. 5 through FIG. 13 are cross-sectional views schematically illustrating the method of forming the wiring electrode terminal 121, lead wire 122, interlayer insulating film 209 and the other elements. In each of FIG. 5 through FIG. 13, figure (a) is a cross-sectional view taken along the line A-A of FIG. 3, figure (b) is a cross-sectional view taken along the line B-B of FIG. 3, and figure (c) is a cross-sectional view taken along the line C-C of FIG. 3.

As shown in FIGS. 5(a) and 5(b), a wiring electrode terminal 121 and a lead wire 122 are formed on the surface of the transparent substrate 201, which is made of glass or the like. Specifically, they are formed as follows. First, a mono-layered or multi-layered first conductive film made of chrome, tungsten, molybdenum, aluminum or the like is formed on the surface of the transparent substrate 201. The first conductive film can be formed by various known sputtering methods. The thickness of the first conductive film is not specifically limited, but 300 nm, for example, is an applicable film thickness. Once the first conductive film is formed, it is patterned by photolithography to form the pattern of the wiring electrode terminal 121 and the pattern of the lead wire 122. Various known etching techniques can be used to pattern the first conductive film. As shown in FIG. 5(b), the first conductive film is not formed between the wiring electrode terminals 121 or between the lead wires 122.

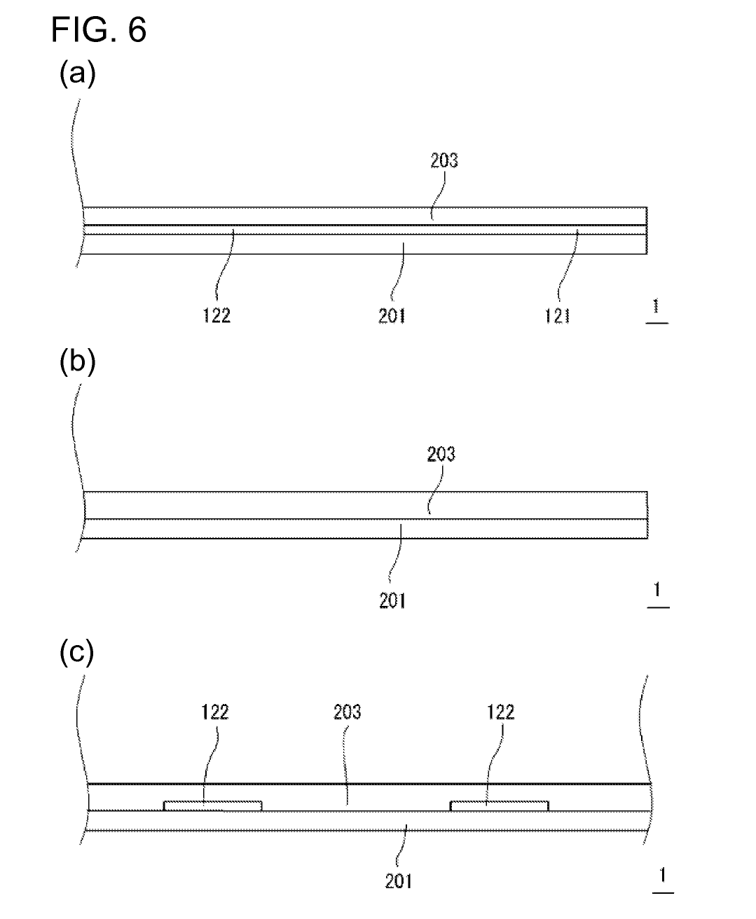

Next, as shown in FIGS. 6(a), 6(b), and 6(c), a first insulating film 203 is formed over the surface of the transparent substrate 201 on which the wiring electrode terminal 121 and the lead wire 122 have already been formed. Silicon nitride (SiNx) or the like can be used for the first insulating film 203. Plasma CVD method can be used to form the first insulating film 203. When the first insulating film 203 is formed, the wiring electrode terminal 121 and the lead wire 122 are covered by the first insulating film 203.

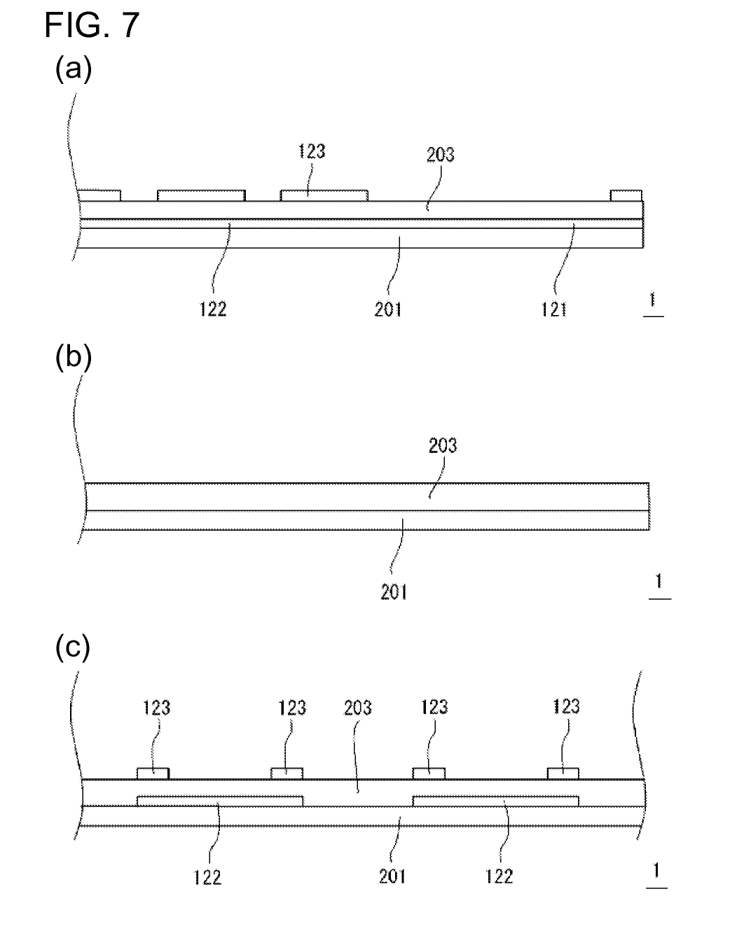

Next, as shown in FIGS. 7(a) and 7(c), sub wirings 123 are formed. The sub wirings 123 are a wiring pattern overlapping the wiring electrode terminals 121 and the lead wires 122 with the first insulating film 203 sandwiched in between. An openings (contact hole) is formed in the portion overlapping the wiring electrode terminal 121, through which the wiring electrode terminal 121 is exposed. As shown in FIG. 7(b), the sub wiring 123 is not formed between the wiring electrode terminals 121 or between the lead wires 122.

Specifically, a conductive film (referred to as “second conductive film”), which is the material of the sub wiring 123, is formed over the transparent substrate 201 that underwent the previous manufacturing steps. Once the second conductive film is formed, it is patterned into the pattern of the sub wiring 123. The second conductive film may be a multi-layered film made of titanium, aluminum, chrome, molybdenum, or the like. The second conductive film can be formed by various known sputtering techniques. The second conductive film can be patterned by dry etching using Cl₂ and BCl₃ gases or wet etching using phosphoric acid, acetic acid, and nitric acid.

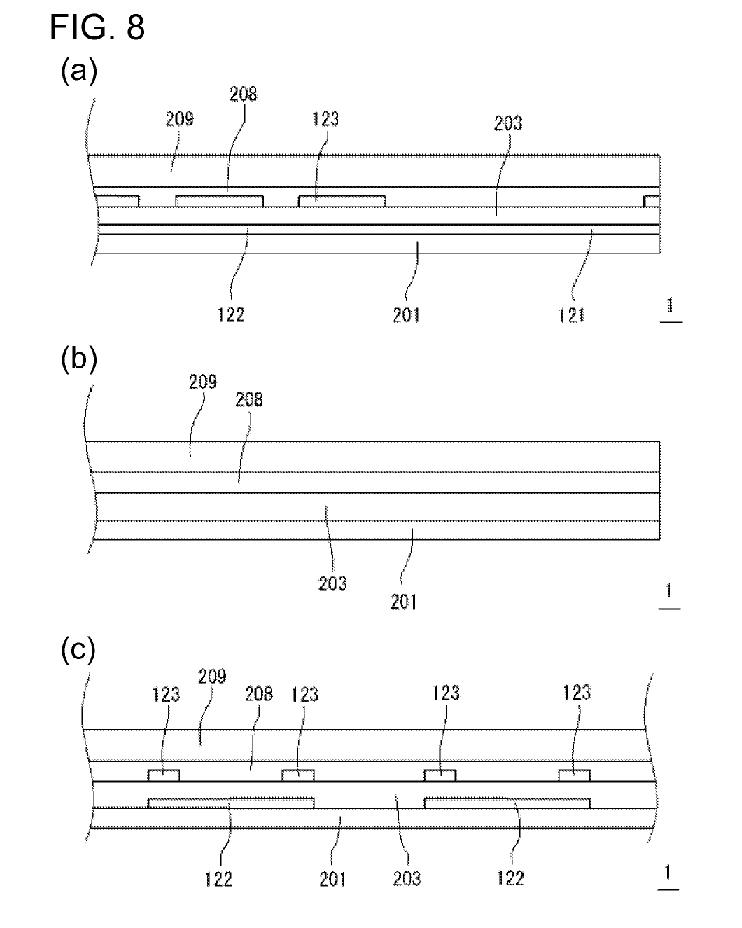

Next, as shown in FIGS. 8(a), 8(b), and 8(c), a second insulating film 208 is formed on the surface of the transparent substrate 201 that underwent the previous manufacturing steps. Then, an interlayer insulating film 209 is formed on the surface of the second insulating film 208. This way, the wiring electrode terminal 121 and the lead wire 122 are covered with the second insulating film 208 and the interlayer insulating film 209. For the second insulating film 208, silicon nitride (SiNx) or like material can be used. The second insulating film 208 can be formed by the plasma CVD method. For the interlayer insulating film 209, an acrylic photosensitive resin material can be used. The interlayer insulating film 209 can be formed by applying the interlayer insulating film 209 material using a spin coater or a slit coater.

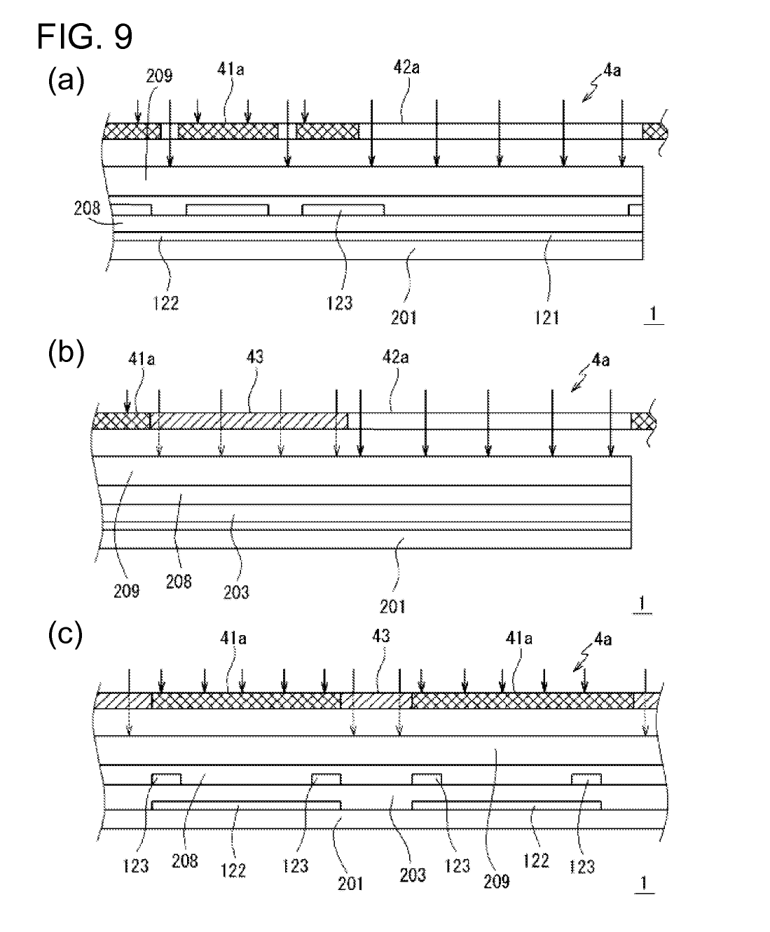

Next, as shown in FIGS. 9(a), 9(b), and 9(c), the interlayer insulating film 209 thus formed is subject to an exposure treatment using a photomask 4a.

In the photomask 4a, light-transmissive regions 42a, light-shielding regions 41a, and halftone regions 43 of prescribed patterns are formed. Specifically, if the interlayer insulating film 209 is made of a positive type photoresist material, the light-transmissive region 42a is formed in the photomask 4a at a location corresponding to the region where the wiring electrode terminal 121 is formed, the light-shielding region 41a is formed at a location corresponding to the region where the lead wire 122 is formed, and the halftone region 43 is formed at a location corresponding to the area between the lead wires 122.

Consequently, by using such photomask 4a, of the interlayer insulating film 209 formed, the portion overlapping the wiring electrode terminal 121 is irradiated with the light energy through the light-transmissive region 42a, and the portion overlapping the lead wire 122 is not irradiated with the light energy. Also, the portion formed between the lead wires 122 is irradiated with the light energy through the halftone region 43. The light energy that passes through the halftone region 43 is weaker than the light energy that passes through the light-transmissive region 42a.

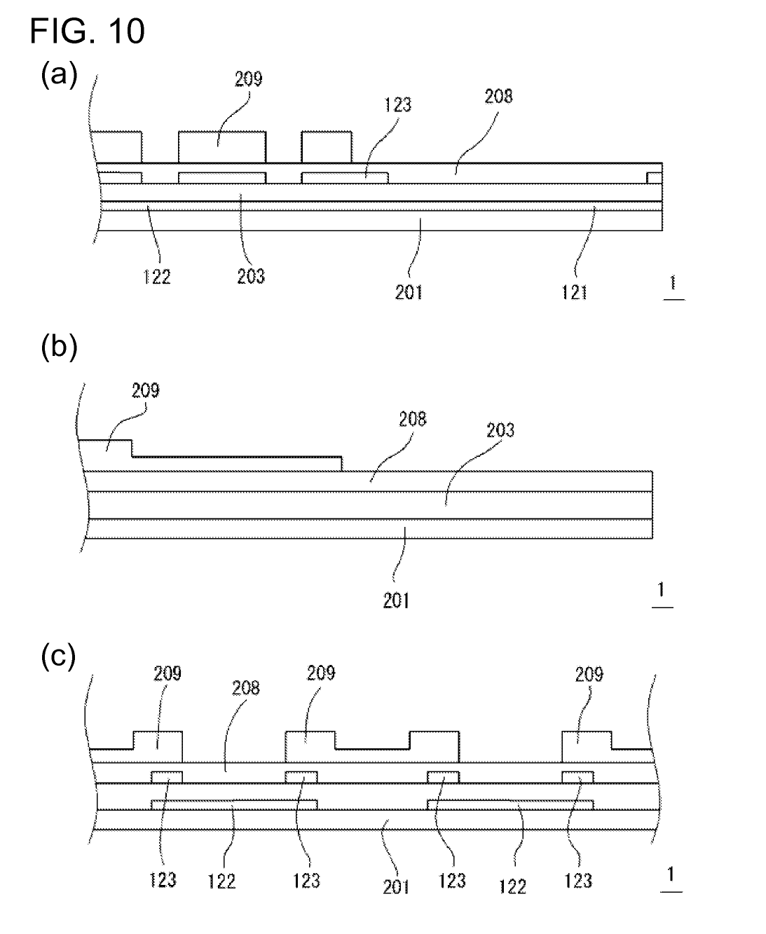

Next, as shown in FIGS. 10(a), 10(b), and 10(c), the photoresist material film that has been subject to light exposure is developed. FIGS. 10(a), 10(b), and 10(c) respectively show the shape of the interlayer insulating film 209 after the development. By the development process, of the photoresist material film, the portion that was irradiated with the light energy through the light-transmissive region 42a of the photomask 4a is removed. As a result, of the interlayer insulating film 209 formed, the portion formed to cover the region where the wiring electrode terminal 121 is formed is removed, and the wiring electrode terminal 121 is exposed. Also, the portion of the interlayer insulating film 209 that was irradiated with the light energy through the halftone region 43 of the photomask 4a has a smaller thickness. As a result, the portion between the lead wires 122 has a smaller thickness than other portions (the portion for which the light was blocked) (see FIGS. 10(b) and 10(c)). Therefore, a stepped surface having a smaller thickness is formed between lead wires 122.

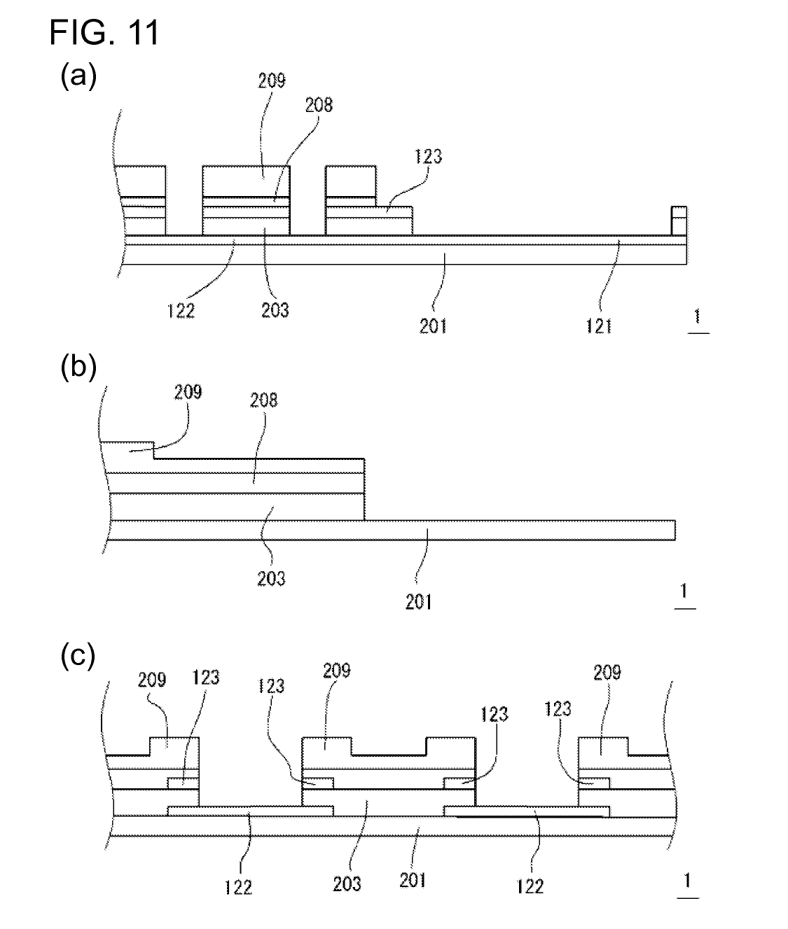

Next, as shown in FIG. 11, the second insulating film 208 is patterned using the patterned interlayer insulating film 209 as a mask. In this patterning process, the first insulating film 203 is also patterned. The first insulating film 203 and the second insulating film 208 can be patterned by dry etching using CF₄+O₂ gases or SF₆+O₂ gases.

Through this patterning, of the second insulating film 208, the portion formed in the region where the wiring electrode terminal 121 is formed and the portion exposed through the openings (contact holes) in the interlayer insulating film 209 are removed. Also, of the first insulating film 203, the portion exposed through the openings formed in the sub wiring 123 is removed. This way, openings are formed to penetrate through the interlayer insulating film 209, the second insulating film 208, the sub wiring 123, and the first insulating film 203, and through these openings, prescribed portions of the lead wire 122 are exposed. Also, the wiring electrode terminal 121 is exposed through the opening formed in the sub wiring 123.

Next, a third conductive film 212 is formed. For the third conductive film 212, ITO (Indium Tin Oxide) having a thickness of about 100 nm may be used. The third conductive film 212 is formed as follows. First, on the surface of the transparent substrate 201 that underwent the previous manufacturing steps, the third conductive film 212 is deposited by sputtering or like method. A photoresist material film 213 is formed on the surface of the third conductive film 212 thus formed. A spin coater or a slit coater, for example, may be used to form the photoresist material film 213.

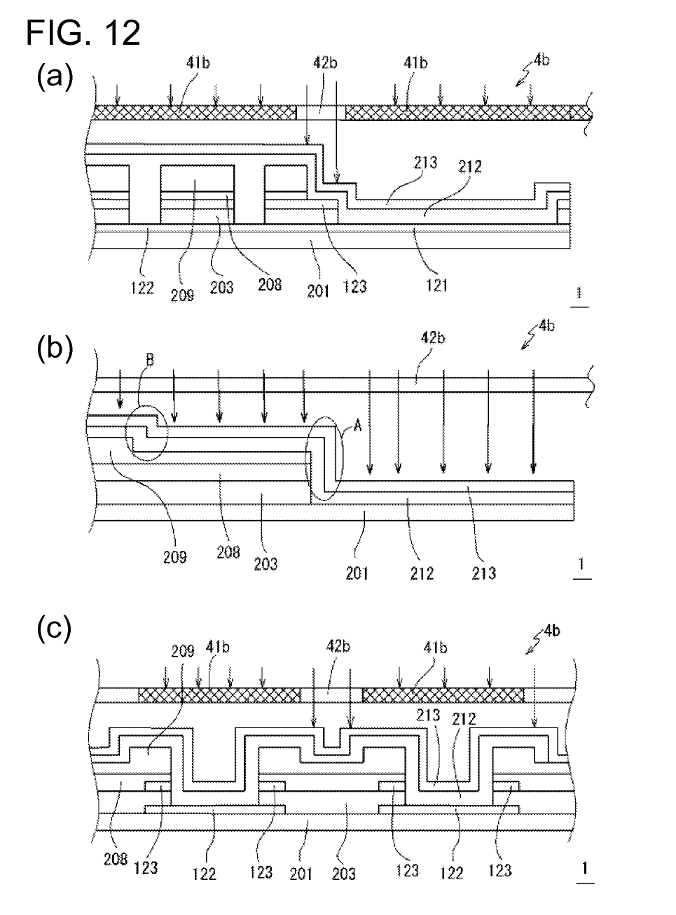

The photoresist material film 213 thus formed is subjected to the exposure using the photomask 4b on which the light-transmissive regions 42b and the light-shielding regions 41b are formed. FIGS. 12(a), 12(b), and 12(c) schematically show the steps of exposure for the photoresist material film 213. The arrows in the figures schematically indicate the radiated light energy.

If the photoresist material film 213 is a positive type, the portion between the wiring electrode terminals 121, the portion between the lead wires 122, and the border portion of the interlayer insulating film 209 are irradiated with the light energy through the light-transmissive regions 42b formed in the photomask 4b. The portion overlapping the wiring electrode terminal 121 and the lead wire 122 are blocked from the light by the light-shielding regions 41b of the photomask 4b.

As shown in FIG. 12, the photoresist material film 213 is also formed on the stepped surface in the border portion of the interlayer insulating film 209 (section A and section B of FIG. 12, for example). The thickness of the photoresist material film 213 formed on the stepped surface of the border portion of the interlayer insulating film 209 depends on the height of the stepped surface of the border portion of the interlayer insulating film 209. According to the embodiments of the present invention, of the border portion of the interlayer insulating film 209, the portion formed between the lead wires 122 has a smaller thickness than other portions (see FIG. 12(b)). Therefore, the thickness of the photoresist material film 213 formed on the stepped surface of the border portion of the interlayer insulating film 209 can be made small, thereby preventing the problem of insufficient exposure on this portion (especially section A).

The photoresist material film 213, which has been subject to the exposure, is developed next. Once the photoresist material film 213 is developed, the portions irradiated with the light energy are removed. Specifically, the portions between the wiring electrode terminals 121, between the lead wires 122, and the portion covering the border portion of the interlayer insulating film 209 are removed. As described above, the problem of the insufficient exposure on the photoresist material film 213 formed on the stepped surface of the border portion of the interlayer insulating film 209 is prevented. Therefore, when the development is conducted, the photoresist material film 213 formed on the stepped surface of the border portion of the interlayer insulating film 209 is completely removed without leaving any film residue.

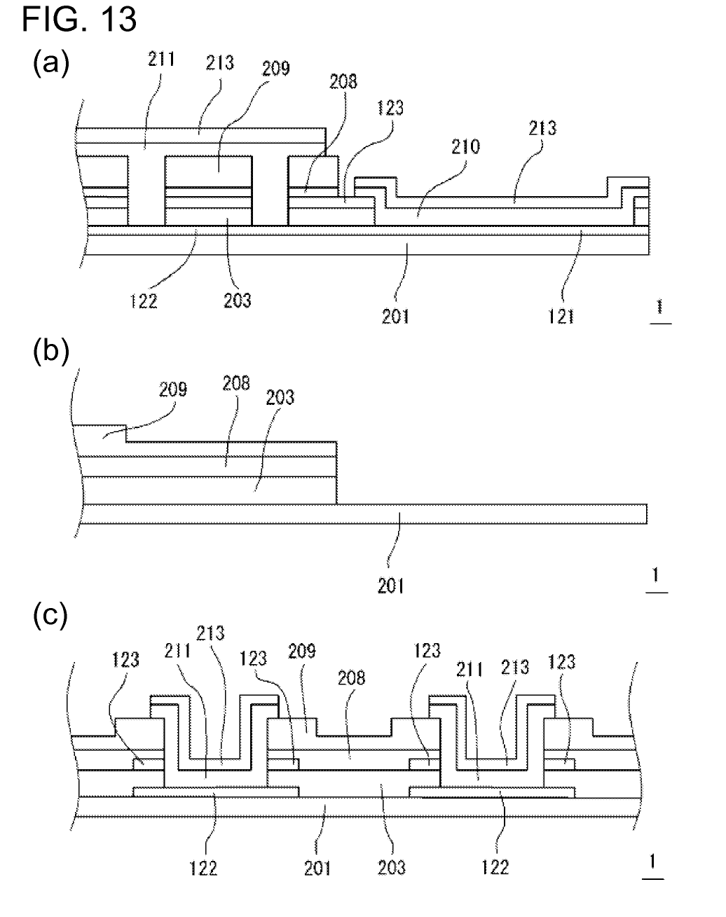

Next, a third conductive film 212 is patterned using the developed photoresist material film 213 as a mask. FIGS. 13(a), 13(b), and 13(c) illustrates the third conductive film 212 that is already patterned. Various known etching techniques can be used to pattern the third conductive film 212. Once patterned, the portion of the third conductive film 212 that is covered by the photoresist material film 213 remains, and other part of the film is removed. More specifically, the third conductive film 212 remains on the surface of the wiring electrode terminal 121 and over the lead wire 122, and the film 212 at other locations (that is, between wiring electrode terminals 121, between lead wires 122, and on the border portion of the interlayer insulating film 209) is removed.

As described above, because the photoresist material film 213 formed on the stepped surface of the border portion of the interlayer insulating film 209 is removed completely, the conductive material film formed on the stepped surface of the border portion of the interlayer insulating film 209 can also be removed completely. Since there is no conductive material film residue on the stepped surface of the border portion of the interlayer insulating film 209, short-circuiting via the conductive material film between the adjacent lead wires 122 or short-circuiting between the adjacent wiring electrode terminals 121 can be prevented.

The photoresist material film 213 is removed next. When the photoresist material film 213 is removed, the configuration of the terminal region 13 of the display panel substrate 1 according to an embodiment of the present invention is as shown in FIG. 4.

When the manufacturing step above is completed, the conductive material film 210 is formed on the surface of the wiring electrode terminal 121, and the conductive material film 211 is formed on the area overlapping the lead wire 122 through the interlayer insulating film 209.

Next, the overall flow of manufacturing steps of display panel substrate 1 according to an embodiment of the present invention is described.

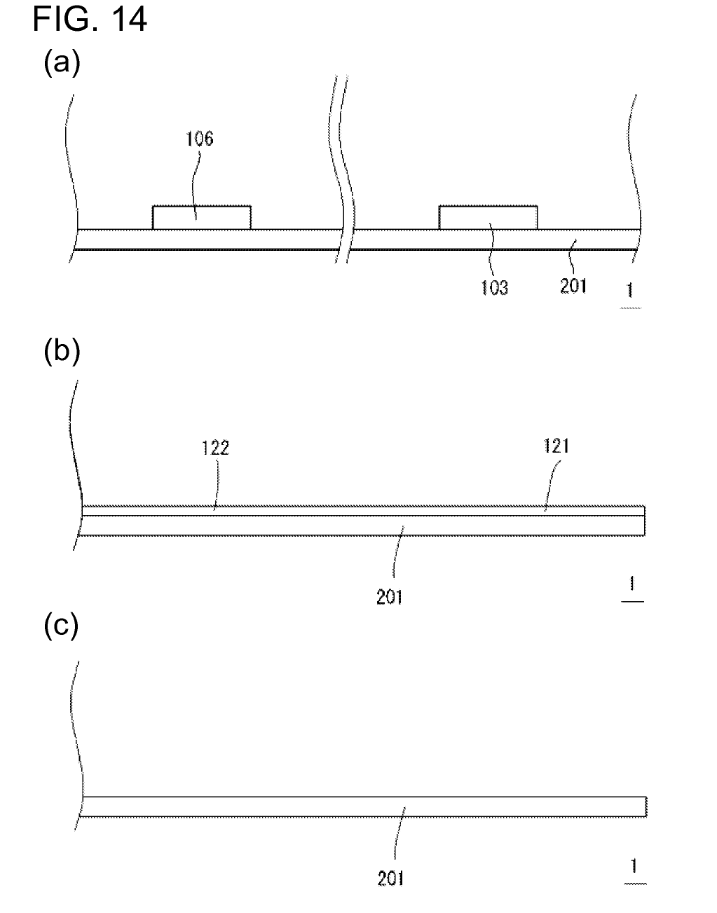

FIG. 14 through FIG. 19 are cross-sectional views schematically illustrating the steps of manufacturing a display panel substrate according to an embodiment of the present invention. Drawings (a) of FIG. 14 through FIG. 19 show the manufacturing steps for formation of pixels and bus lines on the display region 11. Drawings (b) and (c) of FIG. 14 through FIG. 19 show the manufacturing steps for formation of wiring electrode terminals 121 and lead wires 122 on the panel frame region 12. Drawings (b) of FIG. 14 to FIG. 19 are cross-sectional views taken along the line A-A of FIG. 3. Drawings (c) are cross-sectional views taken along the line B-B. Drawings (a) of FIG. 14 through FIG. 19 are schematic cross-sectional views of the display region 11 of the display panel substrate 1 according to an embodiment of the present invention, and not the cross-sectional views taken along a particular line.

As shown in FIG. 14(a), a scanning line 101, an auxiliary capacitance line 103, and a gate electrode 106 of the switching element 105 are formed on the display region 11 of a transparent substrate 201 made of glass or a like material. As shown in FIG. 14(b), the wiring electrode terminal 121 and the lead wire 122 are formed on the panel frame region 12 in this manufacturing step. Also, as shown in FIG. 14(c), nothing is formed between wiring electrode terminals 121 or between lead wires 122 in this manufacturing step.

Specifically, a mono-layered or multi-layered conductive film (i.e., a first conductive film) made of chrome, tungsten, molybdenum, aluminum, or like materials is formed on one surface of the transparent substrate 201. The first conductive film can be formed by various known sputtering or like techniques. The thickness of the first conductive film is not particularly limited, but a film thickness of 300 nm, for example, is applicable.

In the display region 11, as shown in FIG. 14(a), a first conductive film thus formed is patterned into shapes of the scanning line 101, auxiliary capacitance line 103, and gate electrode 106 of the switching element 105. In the panel frame region 12, as shown in FIG. 14(b), the first conductive film is patterned into shapes of the wiring electrode terminal 121 and the lead wire 122. Various known wet etching techniques can be used to pattern the first conductive film. A first conductive film made of chrome can be formed by wet etching using an (NH₄)₂[Ce(NH₃)₆]+HNO₃+H₂O solution.

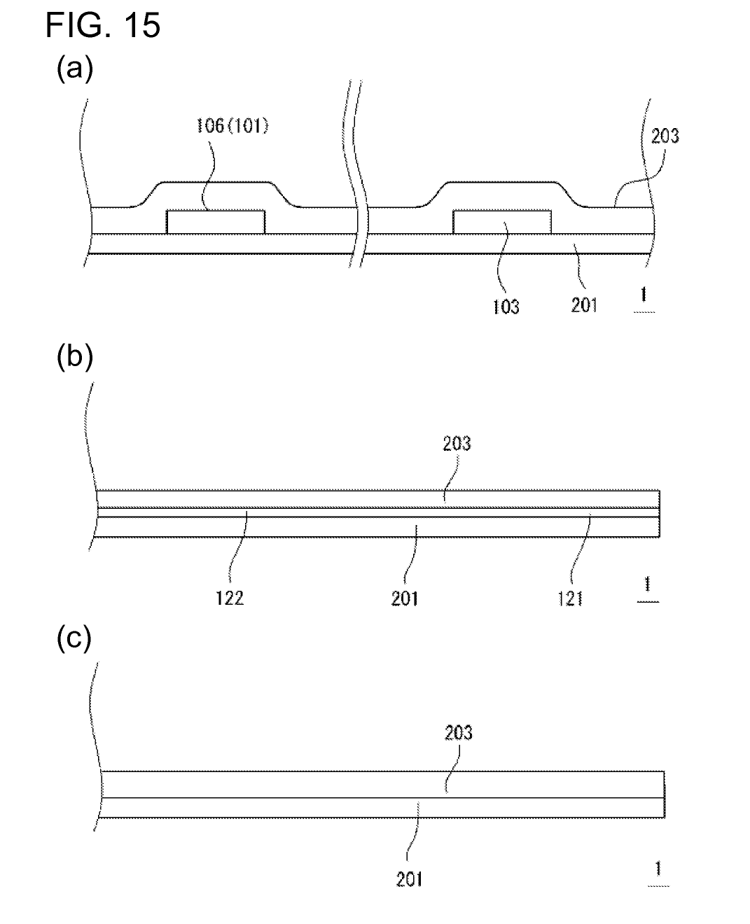

Next, as shown in FIGS. 15(a), 15(b), and 15(c), a first insulating film 203 is formed on the surface of the transparent substrate 201 that underwent the previous manufacturing steps. For the first insulating film 203, SiNx (silicon nitride) with a thickness of about 300 nm, for example, may be used. The first insulating film 203 may be formed by the plasma CVD method. Once the first insulating film is formed, as shown in FIG. 15(a), the scanning line 101, the auxiliary capacitance line 103, and the gate electrode 106 of the switching element 105 are covered by the first insulating film 203 in the display region. Also, in the display region 11, the first insulating film 203 becomes the gate insulating film. In the panel frame region 12, as shown in FIG. 15(b), the wiring electrode terminal 121 and the lead wire 122 are covered by the first insulating film 203.

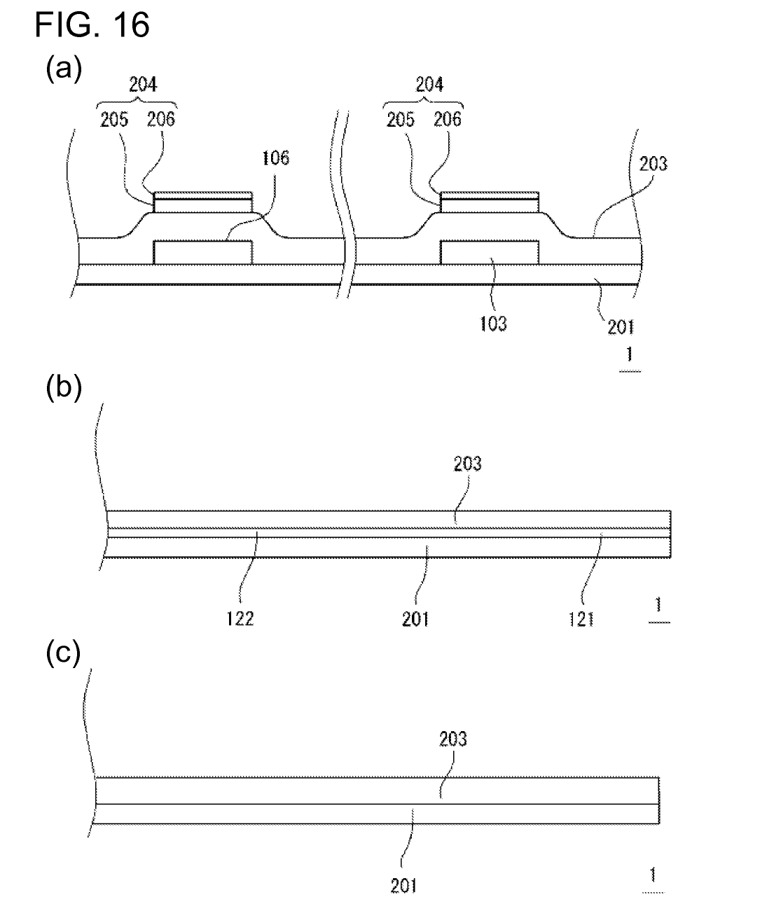

Next, as shown in FIG. 16(a), in the display region 11, a semiconductor film 204 of a prescribed shape is formed on a prescribed location on the first insulating film 203. Specifically, the semiconductor film 204 is formed at the location overlapping the gate electrode 106 via the first insulating film 203, and also at the location overlapping the auxiliary capacitance line 103 via the first insulating film 203. The semiconductor film 204 has a two-layered structure composed of a first sub semiconductor film 205 and a second sub semiconductor film 206. The first sub semiconductor film 205 may be formed of amorphous silicon or the like, having a thickness of about 100 nm. The second sub semiconductor film 206 may be formed of n⁺-type amorphous silicon or the like, having a thickness of about 20 nm.

The first sub semiconductor film 205 serves as an etching stopper layer in the manufacturing step of patterning the data lines and drain lines by etching. The second sub semiconductor film 206 is for enhancing the ohmic contact of a source electrode 107 and a drain electrode 108, which are to be formed later.

The semiconductor film 204 (the first sub semiconductor film 205 and the second sub semiconductor film 206) can be formed by the plasma CVD and photolithography.

That is, using the plasma CVD, the material for the semiconductor film 204 (the first sub semiconductor film 205 and the second sub semiconductor film 206) is deposited on one surface of the transparent substrate 201 that underwent the previous manufacturing steps. The semiconductor film 204 (the first sub semiconductor film 205 and the second sub semiconductor film 206) thus formed is patterned into a particular shape by photolithography or like method. Specifically, a photoresist material layer is formed on the semiconductor film 204. The photoresist material layer may be formed with a spin coater or like technique. Next, the photoresist material layer thus formed is subject to exposure using a photomask, and then development is conducted. As a result, a photoresist material layer of a particular pattern remains on the surface of the semiconductor film 204 in the display region 11.

Then, the semiconductor film 204 is patterned using the patterned photoresist material layer as a mask. The patterning can be performed by wet etching using, for example, an HF+HNO₃ solution, or dry etching using a Cl₂ gas and an SF₆ gas. By this patterning, the semiconductor film 204 (the first sub semiconductor film 205 and the second sub semiconductor film 206) is formed, overlapping the gate electrode 106 via the first insulating film 203, and overlapping the auxiliary capacitance line 103.

In this manufacturing step, as shown in FIGS. 16(b) and 16(c), no semiconductor film is formed in the panel frame region 12.

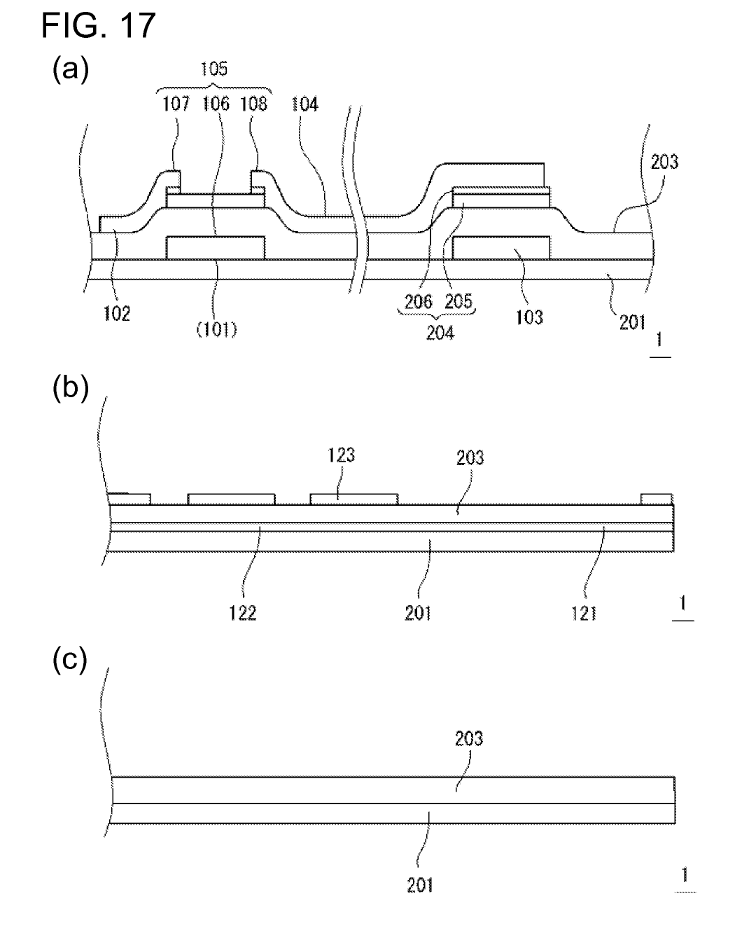

Next, as shown in FIG. 17(a), a data line 102, a drain line 104, a source electrode 107 and a drain electrode 108 of a switching element 105 are formed on the display region 11. Also in this manufacturing process, as shown in FIG. 17(b), a sub wiring 123 is formed in the panel frame region 12 on the surface of the first insulating film 203 at location overlapping the wiring electrode terminal 121 and the lead wire 122. As shown in FIG. 17(c), the sub wiring 123 is not formed between the wiring electrode terminals 121 or between the lead wires 122.

More specifically, first, on the surface of the transparent substrate 201 that underwent the previous manufacturing steps, a conductive film (this conductive film is referred to as “second conductive film”), which is the material for the data line 102, the drain line 104, the source electrode 107 and the drain electrode 108 of the switching element 105, and for the sub wiring 123, is formed. The second conductive film can be formed by sputtering or like technique. Subsequently, the second conductive film thus formed is patterned into a prescribed shape. The second conductive film can be patterned by dry etching using Cl₂ and BCl₃ gases, or by wet etching using phosphoric acid, acetic acid, nitric acid.

By this patterning process, the data line 102, the drain line 104, the source electrode 107 and drain electrode 108 of the switching element 105, all made of the second conductive film, are formed in the display region 11. In the panel frame region 12, the sub wiring 123 is formed of the second conductive film. In this patterning process, a second sub semiconductor film 206 is also etched using the first sub semiconductor film 205 as an etching stopper layer.

The second conductive film has a multi-layered structure having two or more layers made of titanium, aluminum, chrome, molybdenum, or the like. The display panel substrate 1 according to an embodiment of the present invention includes a second conductive film having a two-layered structure. That is, the second conductive film has a two-layered structure composed of the first sub conductive film, which is close to the transparent substrate 201, and the second sub conductive film, which is close to the pixel electrode. The first sub conductive film can be formed of titanium or like material. The second sub conductive film can be formed of aluminum or like material.

As shown in FIG. 17(a), after the manufacturing step described above, the switching element 105 (that is, gate electrode 106, source electrode 107, and drain electrode 108), the data line 102, the scanning line 101, the drain line 104, and the auxiliary capacitance line 103 are formed in the display region 11. Also, as shown in FIG. 17(b), in the panel frame region 12, the wiring electrode terminal 121, the lead wire 122, and the sub wiring 123 are formed.

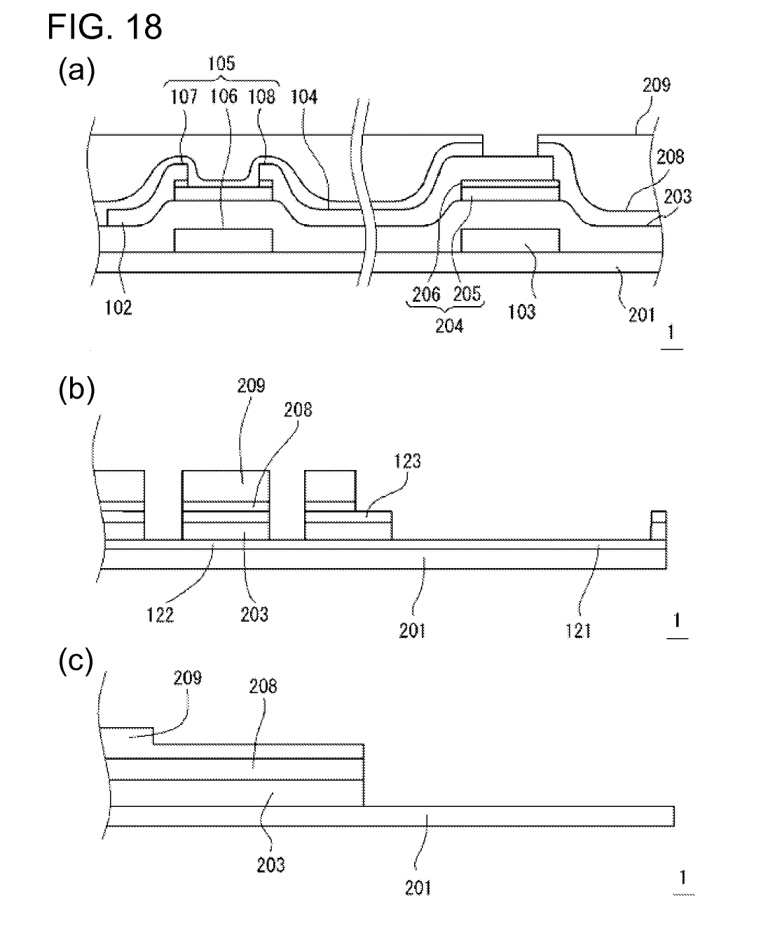

Next, as shown in FIGS. 18(a), 18(b), and 18(c), on the surface of the transparent substrate 201 that underwent the previous manufacturing steps, the second insulating film 208 and the interlayer insulating film 209 are formed. For the second insulating film 208, SiNx (silicon nitride) having a thickness of about 300 nm can be used. For the interlayer insulating film 209, an acrylic photosensitive resin material can be used.

The second insulating film 208 and the interlayer insulating film 209 are formed in the following manner. First, the second insulating film 208 is formed on the surface of the transparent substrate 201 that underwent the previous manufacturing steps. The second insulating film 208 can be formed by the plasma CVD method. After the second insulating film 208 is formed, the interlayer insulating film 209 is formed thereon. The interlayer insulating film 209 can be formed by forming a photoresist material film over the surface of the transparent substrate 201 using a spin coater or like device.

The interlayer insulating film 209 thus formed is patterned into a prescribed pattern by photolithography. Through this patterning, an opening (contact hole) is formed, in the display region 11, to electrically connect the pixel electrode 109 and the drain line 104. In the panel frame region 12, the portion of the interlayer insulating film 209 that overlaps the region in which the wiring electrode terminal 121 is formed is removed. Also, the opening (contact hole) for electrically connecting the lead wire 122 and sub wiring 123 is formed. Furthermore, of the interlayer insulating film 209 formed in the panel frame region 12, the portion formed between the lead wires 122 is made thinner than other portion of the film.

In the exposure process, if the photoresist material is a positive type, the location where the opening is to be formed is irradiated with the light energy, and the location where the interlayer insulating film 209 is to be preserved is shielded from the light. In the panel frame region 12, of the interlayer insulating film 209, the portion formed in the region where the wiring electrode terminal 121 is formed is irradiated with the light energy, and the portion formed in the region where the lead wire 122 is formed is shielded from the light. The portion between the lead wires 122 is irradiated with the light energy through the half-tone region formed in the photomask. That is, the interlayer insulating film 209 formed between the lead wires 122 is irradiated with a weaker light energy compared to the interlayer insulating film 209 formed in the region where the wiring electrode terminal 121 is formed.

Once the light-exposed interlayer insulating film 209 is developed, the portion irradiated with the light energy is removed, and the portion shielded from the light energy is preserved. The portion of the interlayer insulating film 209 exposed to the light through the halftone region is preserved, but that portion has a smaller thickness than the portion shielded from the light. Therefore, in the display region 11, an opening is formed to electrically connect the pixel electrode 109 and the drain line 104. In the panel frame region 12, the portion of the interlayer insulating film 209 overlapping the wiring electrode terminal 121 is removed. Also, the portion of the interlayer insulating film 209 formed between the lead wires 122 becomes thinner than the other portions of the interlayer insulating film 209.

Once the interlayer insulating film 209 is patterned and the prescribed portions are removed, the second insulating film 208 is exposed through where the interlayer insulating film 209 was removed. Next, the second insulating film 208 is patterned by using the patterned interlayer insulating film 209 as a mask. Through this patterning, the portion of the second insulating film 208 that is exposed by the interlayer insulating film 209 (that is, the portion not covered by the interlayer insulating film 209) is removed. Through this patterning, the first insulating film 203 is also patterned. More specifically, in the panel frame region 12, the first insulating film 203 exposed through the opening formed in the sub wiring 123 is removed. As a result, the wiring electrode terminal 121 is exposed through the openings formed in the first insulating film 203 and in the sub wiring 123. Also, prescribed portions of the lead wire 122 are exposed through the openings formed in the interlayer insulating film 209, the opening formed in the sub wiring 123, and the openings formed in the first insulating film 203.

The interlayer insulating film 209 and the first insulating film 203 are patterned by dry etching using CF₄+O₂ gases or SF₆+O₂ gases.

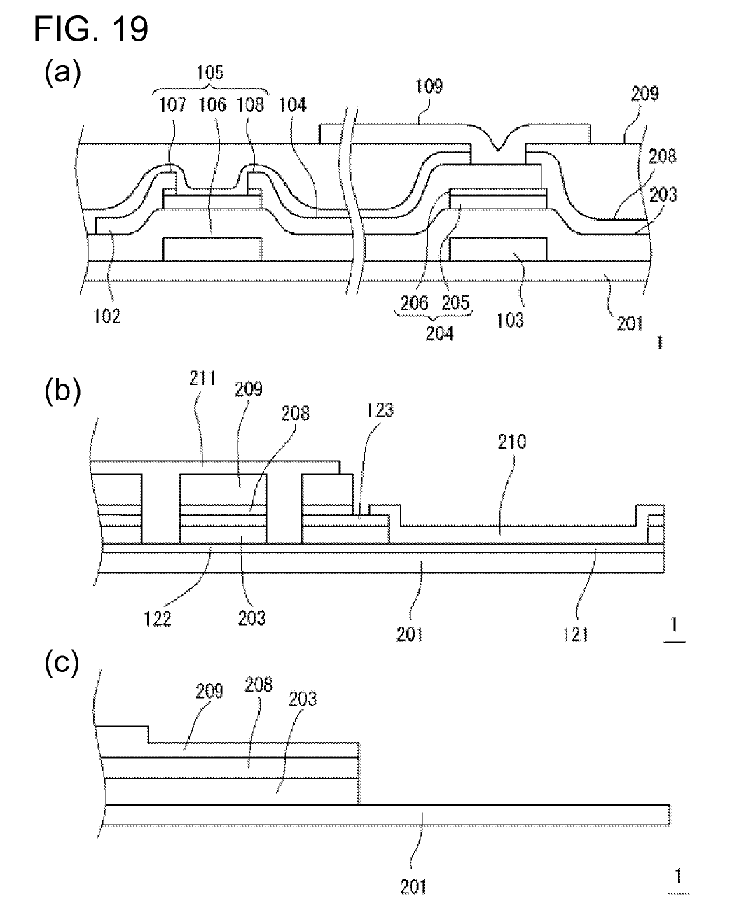

Next, as shown in FIG. 19(a), a pixel electrode 109 is formed in the display region 11. As shown in FIG. 19(b), a conductive material film 210, which overlaps the wiring electrode terminal 121, and a conductive material film 211, which overlaps the lead wire 122 are formed in the panel frame region 12 in this manufacturing step.

Specifically, first, on the surface of the transparent substrate 201 that underwent the previous manufacturing steps, the material for the pixel electrode 109 and the conductive material films 210 and 211 (the material for the pixel electrode 109 and conductive material films 210 and 211 is herein referred to as “third conductive film”) is formed by sputtering or like method. The third conductive film can be made of ITO (Indium Tin Oxide) having a thickness of about 100 nm. Next, a photoresist material film is formed on the surface of the third conductive film thus formed. The photoresist material film formed is irradiated with the light energy through a photomask having prescribed light-shielding and light-transmitting patterns.

In the display region 11, if the photoresist material is a positive type, the portion of the photoresist material that will become the pixel electrode 109 is shielded from the light, and other portion is irradiated with the light energy. In the panel frame region 12, the portion between the wiring electrode terminals 121, between the lead wires 122, and the border portion of the interlayer insulating film 209 is irradiated with the light energy, and the portion overlapping the wiring electrode terminal 121 and the lead wire 122 are shielded from the light.

Next, the photoresist material irradiated with the light energy is developed. Once the photoresist material is developed, the portion irradiated with the light energy is removed. In the display region 11, the portion corresponding to the pixel electrode 109 is preserved, and the portion corresponding to the area between the pixel electrodes 109 is removed. In the panel frame region 12, the portion between the wiring electrode terminals 121, the portion between the lead wires 122, and the portion covering the border portion of the interlayer insulating film 209 are removed.

Next, the third conductive film is patterned using the developed photoresist material as a mask. The third conductive film can be patterned by wet etching using ferric chloride. Through this patterning, the portions of the third conductive film that are covered by the photoresist material are preserved, and other portions are removed. As a result, in the display region 11, the pixel electrode 109 remains and the portion between the pixel electrodes 109 is removed. In the panel frame region 12, the third conductive film on the surface of the wiring electrode terminal 121 and the portion overlapping the lead wire 122 are preserved, and other portions of the film are removed. As a result, the conductive material film 210 is formed of the third conductive film on the surface of the wiring electrode terminal 121. The conductive material film 211 is formed at a location overlapping the lead wire 122 via the interlayer insulating film 209. The conductive material film 210 formed on the surface of the wiring electrode terminal 121 and the conductive material film 211 formed overlapping the lead wire 122 are physically separated from each other.

The display panel substrate 1 according to an embodiment of the present invention is manufactured by undergoing the steps described above.

Next, the method for manufacturing a display panel according to an embodiment of the present invention is described. The method for manufacturing the display panel according to an embodiment of the present invention includes the steps of: manufacturing an TFT array substrate, manufacturing a color filter, and manufacturing a panel (i.e., cell manufacturing). The TFT array substrate is manufactured as described above.

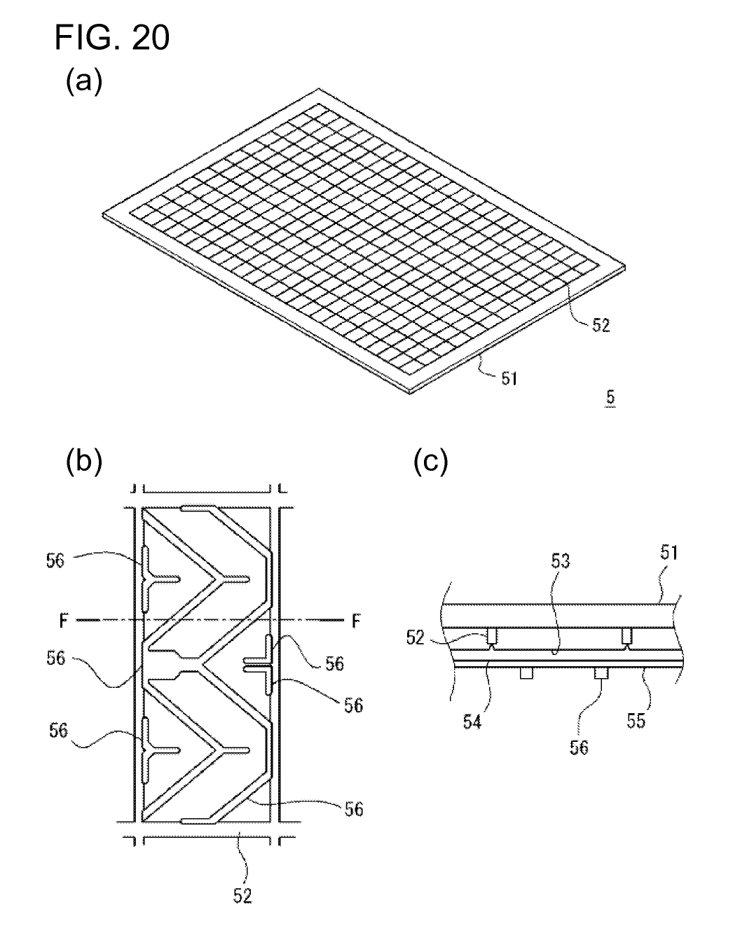

The configuration of the color filter 5 and the method of manufacturing the color filter are as follows. FIG. 20 schematically shows the configuration of the color filter 5. Specifically, FIG. 20(a) is a schematic perspective view of the overall structure of the color filter 5. FIG. 20(b) is a plan view showing the configuration of a single pixel formed on the color filter 5. FIG. 20(c) is a cross-sectional view taken along the line F-F of FIG. 20(b), illustrating the cross-sectional structure of a pixel.

As shown in FIGS. 20(a), 20(b), and 20(c), for the color filter 5, a black matrix 52 is formed on the surface of one side of a transparent substrate 51, which is made of glass or like material. In each box of the black matrix 52, a color layer 53 made of color resist of red, green, or blue, is formed. The boxes in which the color layers 53 of respective colors are formed are arranged in a particular order. A protective film 54 is formed on the surface of the black matrix 52 and the color layers 53 of respective colors. A common electrode 55 is formed on the surface of the protective film 54. Alignment control projections 56 for controlling the alignment of the liquid crystal are formed on the surface of the common electrode 55.

The color filter formation process includes steps of forming the black matrix, forming the color layer, forming the protective film, and forming the common electrode.

For example, in the resin BM method, a black matrix is formed as follows. First, a BM resist (a photosensitive resin material containing a black color agent) or the like is applied on the surface of a transparent substrate. Next, the BM resist applied is formed into a prescribed pattern by photolithography or like method. Thus, a black matrix 52 of the prescribed pattern is obtained.

In the color layer formation step, color layers 53 of red, green, and blue for color display are formed. In the color resist method, for example, the color layers 53 are formed in the following manner. First, a color resist (a solution prepared by dispersing a pigment of a prescribed color in a photosensitive material) is applied on the transparent substrate on which the black matrix 52 has been formed. Next, the applied color resist is formed into a prescribed pattern by photolithography or like method. This process is performed for colors of red, green, and blue. This way, color layers 53 of each of these colors are obtained. Alternatively, using an inkjet printing machine, a color layer material (for example, a resin composition containing a particular color agent) may be dripped into each box of the black matrix 52.

The method used for the black matrix formation is not limited to the resin BM method. Various known methods such as a chromium BM method and a lamination method may be used. Also, the method used for the color layer formation is not limited to the color resist method. Various known methods such as printing, dyeing, electric deposition, a transfer method, and etching may also be used. The backside exposure method, where the color layer 53 is formed first and the black matrix 52 is formed later, is another possible technique.

In the protective film formation process, a protective film 54 is formed on the surface of the black matrix 52 and the surface of the color layer 53. For example, a protective film material can be applied on the surface of the transparent substrate 51 that underwent the previous manufacturing steps, using a spin coater (the entire surface application method). Alternatively, the protective film 54 of a prescribed pattern can be formed by printing, photolithography, or like method (patterning method). An acrylic resin or epoxy resin, for example, can be used as the protective film material.

In the step of forming the common electrode, a common electrode 55 is formed on the surface of the protective film 54. In the masking method, for example, the common electrode 55 is formed by disposing a mask on the surface of the transparent substrate 51 that underwent the previous manufacturing steps, and vapor-depositing indium tin oxide (ITO) or like material by sputtering or like method.

Next, alignment control projections 56 are formed. The alignment control projections 56 are made of a photosensitive resin or like material, and are formed by photolithography or like method. A photosensitive material is applied on the surface of the transparent substrate 51, which underwent the manufacturing steps described above, and is subject to the exposure for a prescribed pattern through a photomask. Then, unnecessary portion is removed in the subsequent development step. The alignment control projections 56 of the prescribed pattern are thus obtained.

Thus, a color filter 5 is made through the manufacturing steps described above.

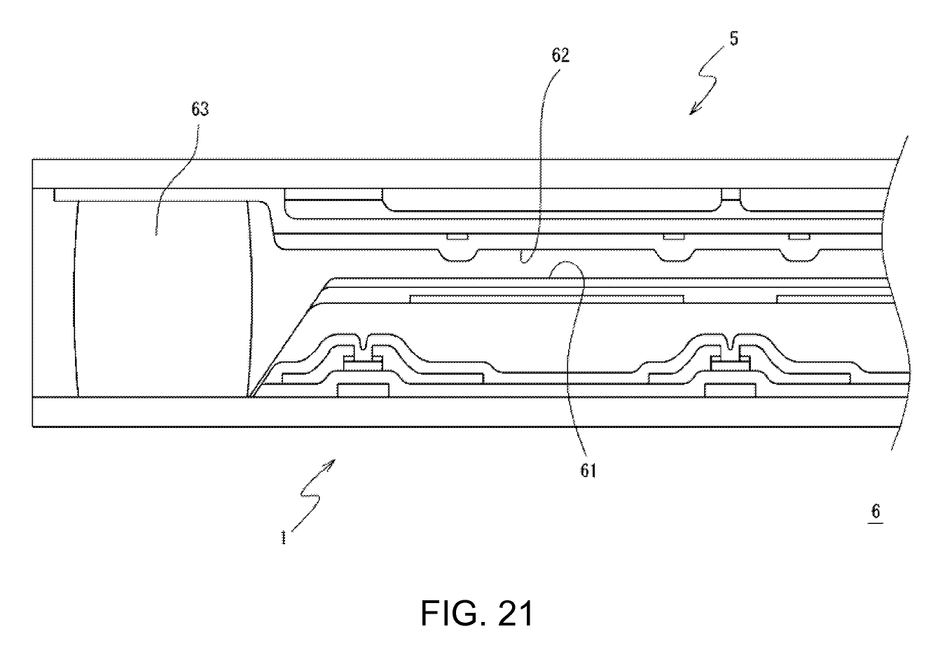

Next, steps for manufacturing the panel is described. FIG. 21 is a cross-sectional view schematically illustrating the structure of a portion of a display panel 6 according to an embodiment of the present invention. First, alignment films 61 and 62 are formed on the surface of the TFT array substrate obtained through the manufacturing steps described above (that is, the display panel substrate 1 according to an embodiment of the present invention) and on the surface of the color filter 5. Then, the alignment films 61 and 62 are subjected to an alignment treatment (a configuration in which the alignment treatment is not performed is also possible). Subsequently, the display panel substrate 1 according to an embodiment of the present invention and the color filter 5 are bonded together. Furthermore, liquid crystal is introduced between the display panel substrate 1 of the embodiment of the present invention and the color filter 5.

The alignment films 61 and 62 are formed on the surface of the display panel substrate 1 and on the surface of the color filter 5 according to an embodiment of the present invention as follows. First, an alignment material is applied on the surface of the display region of the display panel substrate 1 of an embodiment of the present invention and on the surface of the display region of the color filter 5 using an alignment material application machine or like device. The alignment material is a solution containing substance that is to be an alignment film material. An inkjet type printing machine (dispenser) can be used as the alignment material application machine.

The coated alignment materials 61 and 62 are heated and baked in an alignment film baking machine or like device.

Next, an alignment treatment is performed on the baked alignment films 61 and 62. Various known techniques can be used for the alignment treatment. For example, the surface of the alignment film can be finely scratched using a rubbing roller or like equipment, or a photoalignment treatment may be conducted in which the surface of the alignment film is irradiated with the light energy such as ultraviolet rays to adjust the surface condition. The alignment treatment as mentioned above, however, does not need to be performed.

Next, a sealing material 63 is applied so as to surround the display region 11 of the display panel substrate 1 of an embodiment of the present invention, using a seal patterning machine or like device.

Then, spacers for maintaining a prescribed cell gap are dispersed on the surface of the display panel substrate 1 of an embodiment of the present invention, using a spacer dispersing device or like equipment. Alternatively, column-shaped spacers may be formed on the surface of the display panel substrate 1 of an embodiment of the present invention or on the surface of the color filter 5. In this case, the spacer dispersal is not necessary. Subsequently, liquid crystal is dripped in the region surrounded by the sealing material 63 on the surface of the display panel substrate 1 of an embodiment of the present invention, using a liquid crystal dripping device or like equipment.

Next, under a reduced-pressure atmosphere, the display panel substrate 1 of any one of the embodiments of the present invention and the color filter 5 are bonded together. Then, the sealing material 63 is irradiated with ultraviolet rays to cure the sealing material 63. Alternatively, liquid crystal can be introduced between the display panel substrate 1 of an embodiment of the present invention and the color filter 5 after the sealing material 63 is cured.

Through the manufacturing steps described above, a display 6 according to an embodiment of the present invention can be obtained.

While embodiments the present invention are described herein with reference to figures, it should be understood that the invention is not limited thereto. Needless to say, various changes can be made within the spirit of the present invention.

1. A display panel substrate comprising:
a plurality of wiring electrode terminals for connecting external wiring substrates;
a plurality of lead wires respectively and electrically connected to said plurality of wiring electrode terminals;
an interlayer insulating film covering said plurality of lead wires;
a conductive material film formed to overlap respective one of said plurality of wiring electrode terminals, and electrically connected to the respective one of said plurality of wiring electrode terminals; and
a conductive material film formed to overlap respective one of said plurality of lead wires through the interlayer insulating film, and electrically connected to the respective one of said plurality of lead wires,
wherein said plurality of lead wires are formed in parallel with each other, and
wherein, in a border portion of said interlayer insulating film, a portion that is formed between said plurality of lead wires has a smaller thickness than a portion formed to overlap said plurality of lead wires.

2. The display panel substrate according to claim 1, wherein said conductive material film, which is formed to overlap said lead wire through said interlayer insulating film and is electrically connected to said lead wire, is electrically connected to said lead wire through an opening formed in said interlayer insulating film.

3. The display panel substrate according to claim 1,
wherein said conductive material film formed to overlap respective one of said plurality of wiring electrode terminals and said conductive material film formed to overlap respective one of said plurality of lead wires through said interlayer insulating film are separated from each other in the border portion of said interlayer insulating film, and
wherein said conductive material films formed respectively to overlap adjacent respective one of said plurality of lead wires through said interlayer insulating film are separated from each other.

4. The display panel substrate according to claim 1, wherein, in the conductive material film formed to overlap said lead wire through said interlayer insulating film, a portion in proximity to the border portion of said interlayer insulating film has a smaller width than other portions.

5. The display panel substrate according to claim 1,
wherein, in the conductive material film formed to overlap said lead wire through said interlayer insulating film, a portion in proximity to the border portion of said interlayer insulating film is formed to have a smaller width than other portions, and
wherein said portion having the smaller width than other portions has a wider spacing between itself and a conductive material film formed to overlap an adjacent lead wire through said interlayer insulating film.

6. A display panel comprising the display panel substrate according to claim 1 and an opposite substrate,
wherein said display panel substrate and said opposite substrate are disposed opposite to each other with a prescribed space in between, and
wherein the space between said display panel substrate and said opposite substrate is filled with liquid crystal.
